(19) United States
(12) Patent Application Publication
(10) Pub. No.: US 2015/0098479 A1
(43) Pub. Date: Apr. 9, 2015

(54) OPTICAL PULSE OUTPUT APPARATUS AND METHOD FOR CONTROLLING WIDTH AND INTENSITY OF OPTICAL PULSE

(71) Applicant: Electronics and Telecommunications Research Institute, Daejeon (KR)

(72) Inventors: Jyung Chan LEE, Daejeon (KR); Seung Il MYONG, Daejeon (KR)

(21) Appl. No.: 14/303,890

(22) Filed: Jun. 13, 2014

(30) Foreign Application Priority Data
Oct. 7, 2013 (KR) 10-2013-0119280

(51) Int. Cl. H01S 5/062; H01S 3/11

(52) U.S. Cl. CPC H01S 5/06216; H01S 3/11
USPC 372/25

(57) ABSTRACT

An optical pulse output apparatus and method for controlling a width and an intensity of an optical pulse are provided. The optical pulse output apparatus may include a laser driver to control an optical pulse output by a laser, based on a plurality of channel signals, and a channel delay unit to delay at least one of the plurality of channel signals.

### CROSS-REFERENCE TO RELATED APPLICATION

This application claims the benefit of Korean Patent Application No. 10-2013-0119280, filed on Oct. 7, 2013, in the Korean Intellectual Property Office, the disclosure of which is incorporated herein by reference.

### BACKGROUND

1. Field of the Invention

The present invention relates to an optical pulse output apparatus and method for controlling a width and an intensity of an optical pulse, and more particularly, to an apparatus and method for controlling a width and an intensity of an output optical pulse, by delaying an external input channel, or by controlling a maximum current value.

2. Description of the Related Art

Optical time-domain reflectometers (OTDRs) are typically used to monitor optical cables, in order to locate and diagnose faults in optical cables.

Korean Patent Application No. 10-2011-0111454, published on Oct. 11, 2011, discloses an OTDR technology of calculating a distance distribution and a quantity of light in each point to which light incident on an optical fiber is reflected and returned, and of measuring a loss or a damaged location of the optical fiber.

In the OTDR technology, an intensity and a width of a pulse of a light source incident on an optical fiber needs to be changed based on a length of the optical fiber.

However, when a component of a laser is changed to change the intensity and the width of the pulse of the light source, problems of unstable lasing may occur in a transversal mode and a longitudinal mode of the light source and a coherent length of the light source, as well as, a line width and a relative intensity noise of the light source.

Accordingly, there is a need for a method of changing an intensity and a width of an optical pulse, instead of changing a component of a laser that outputs the optical pulse.

### SUMMARY

An aspect of the present invention provides an apparatus and method for guaranteeing stability of a light source and freely changing a width and an intensity of an optical pulse, by delaying an external input channel, and by controlling a maximum current value.

According to an aspect of the present invention, there is provided an optical pulse output apparatus including: a laser driver to control an optical pulse output by a laser, based on a plurality of channel signals; and a channel delay unit to delay at least one of the plurality of channel signals.

The laser deriver may determine a width of the optical pulse, based on a result obtained by delaying the at least one channel signal.

When an amount of time by which the at least one channel signal is delayed increases, the laser driver may increase the width of the optical pulse.

When the channel delay unit does not delay the at least one channel signal, the laser driver may determine the width of the optical pulse, based on a width of each of the plurality of channel signals.

The optical pulse output apparatus may further include a maximum current controller to control a maximum current of the laser driver.

The laser driver may determine an intensity of the optical pulse, based on the maximum current.

According to another aspect of the present invention, there is provided an optical pulse output apparatus including: a laser driver to control an optical pulse output by a laser; and a maximum current controller to control a maximum current of the laser driver.

According to another aspect of the present invention, there is provided an optical pulse output method including: delaying at least one of a plurality of channel signals; and controlling an optical pulse output by a laser, based on the plurality of channel signals.

According to another aspect of the present invention, there is provided an optical pulse output method including: controlling a maximum current of a laser driver; and controlling an optical pulse output by a laser, based on the maximum current.

### EFFECT

According to embodiments of the present invention, it is possible to guarantee stability of a light source and to freely change a width and an intensity of an optical pulse, by delaying an external input channel, and by controlling a maximum current value.

### BRIEF DESCRIPTION OF THE DRAWINGS

These and/or other aspects, features, and advantages of the invention will become apparent and more readily appreciated from the following description of exemplary embodiments, taken in conjunction with the accompanying drawings of which:

FIG. 1 is a block diagram illustrating an optical pulse output apparatus according to an embodiment of the present invention;

FIG. 2 is a diagram illustrating a configuration of the optical pulse output apparatus of FIG. 1;

FIG. 3 is a diagram illustrating an example of an optical pulse according to an embodiment of the present invention;

FIG. 4 is a diagram illustrating an example of a change in an intensity of an optical pulse according to an embodiment of the present invention;

FIG. 5 is a diagram illustrating an example of a change in a width of an optical pulse according to an embodiment of the present invention;

FIG. 6 is a diagram illustrating an example of a change in a width and an intensity of an optical pulse according to an embodiment of the present invention; and

FIG. 7 is a flowchart illustrating an optical pulse output method according to an embodiment of the present invention.

### DETAILED DESCRIPTION

Reference will now be made in detail to exemplary embodiments of the present invention, examples of which are illustrated in the accompanying drawings, wherein like reference numerals refer to the like elements throughout. Exemplary embodiments are described below to explain the present invention by referring to the figures.

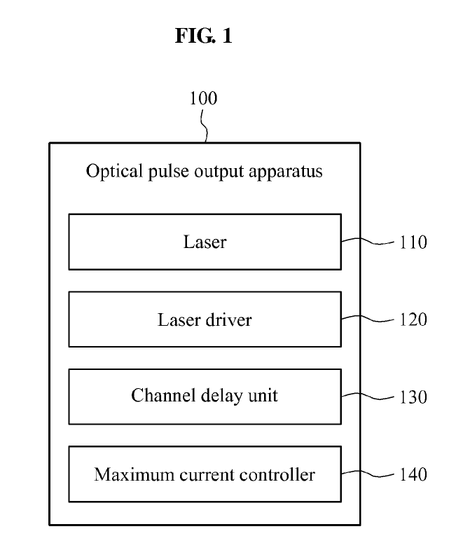

FIG. 1 is a diagram illustrating an optical pulse output apparatus 100 according to an embodiment of the present invention.

Referring to FIG. 1, the optical pulse output apparatus 100 may include a laser 110, a laser driver 120, a channel delay unit 130, and a maximum current controller 140.

The laser 110 may output an optical pulse.

The laser driver 120 may control the optical pulse output by the laser 110, using a plurality of channel signals. The laser driver 120 may include, for example, a two-channel laser diode (LD) driver, that is, a laser driver using a channel A and a channel B. The channels A and B may refer to electrical signals that are used to generate an optical pulse and that have the same widths and the same periods.

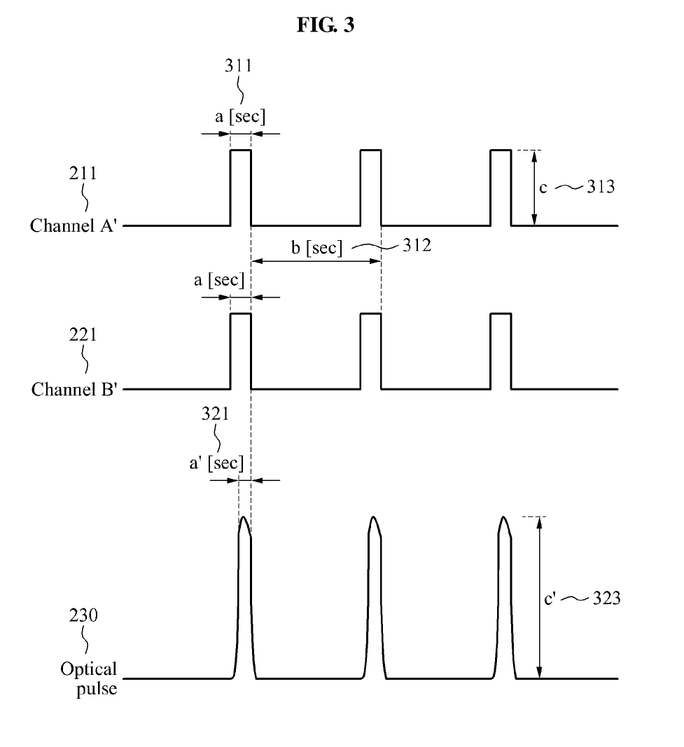

A change in an intensity and a width of an optical pulse determined by the laser driver 120, based on an operation of each of the channel delay unit 130 and the maximum current controller 140 will be further described with reference to FIGS. 3 through 6 below.

The channel delay unit 130 may delay at least one of the plurality of channel signals input to the laser driver 120. For example, the channel delay unit 130 may be a time delay block “two-channel delay” to independently control a time delay of the channels A and B.

In this instance, the laser driver 120 may determine a width of the optical pulse output by the laser 110, based on a result of delay of the at least one channel signal. The result of the delay of the at least one channel signal may include, for example, at least one of information on whether at least one of the plurality of channel signals is delayed, and an amount of time by which the at least one channel signal is delayed.

For example, as an amount of time by which at least one channel signal is delayed by the channel delay unit 130 increases, the laser driver 120 may increase the width of the optical pulse output by the laser 110.

When the channel delay unit 130 does not delay the at least one of the plurality of channel signals, the laser driver 120 may determine the width of the optical pulse output by the laser 110, based on a width of each of the plurality of channel signals.

The maximum current controller 140 may control a maximum current, that is, a maximum value of a current transferred by the laser driver 120 to the laser 110. The maximum current controller 140 may be, for example, a maximum current control end “Current Max.cont.” of the laser driver 120.

In this instance, the laser driver 120 may determine an intensity of the optical pulse output by the laser 110, based on the maximum current.

For example, when the maximum current controller 140 increases the maximum current, the laser driver 120 may increase the intensity of the optical pulse output by the laser 110.

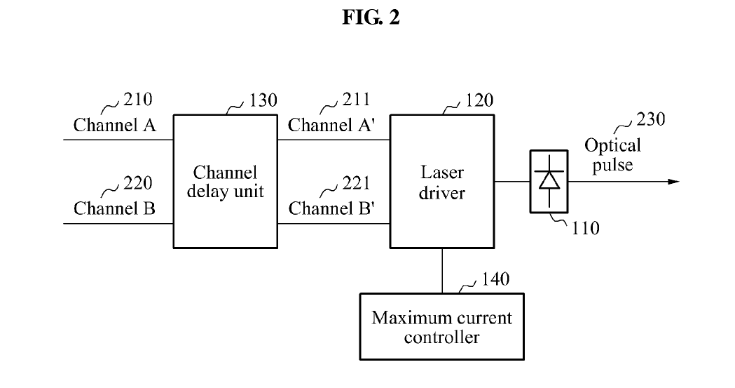

FIG. 2 is a diagram illustrating a configuration of the optical pulse output apparatus 100 of FIG. 1.

As shown in FIG. 2, the optical pulse output apparatus 100 may receive a channel A 210 and a channel B 220 that are electrical signals used to generate a light source of an optical time-domain reflectometer (OTDR).

The channel delay unit 130 may control a time delay for the channel A 210 and the channel B 220, and may output a channel A′ 211 and a channel B′ 221. In this instance, different time domains may be applied to the channel A′ 211 and the channel B′ 221.

For example, the channel delay unit 130 may delay only the channel B 220, not the channel A 210. In this example, the channel A′ 211 may be identical to the channel A 210, however, the channel B′ 221 may be different from the channel B 220.

Additionally, the laser driver 120 may generate a control signal to control the laser 110 to output an optical pulse, using the channel A′ 211 and the channel B′ 221 received from the channel delay unit 130. A maximum current of the control signal generated by the laser driver 120 may be determined by the maximum current controller 140.

The laser 110 may output an optical pulse 230, based on the control signal generated by the laser driver 120. A width of the optical pulse 230 output by the laser 110 may correspond to the channel A′ 211 and the channel B′ 221 output by the channel delay unit 130. Additionally, an intensity of the optical pulse 230 may correspond to the maximum current determined by the maximum current controller 140.

FIG. 3 is a diagram illustrating an example of an optical pulse according to an embodiment of the present invention.

The channel A′ 211 and the channel B′ 221 output by the channel delay unit 130 may have the same width, for example a width a 311, the same period, for example a period b 312, and the same intensity, for example an intensity c 313. In the following description, a width and a period may be set in seconds (sec).

A period of the optical pulse 230 output by the laser 110 based on the channel A′ 211 and the channel B′ 221 may be identical to the period b 312 of each of the channel A′ 211 and the channel B′ 221. On the other hand, the optical pulse 230 may have a width a′ 321, and an intensity c′ 323, as shown in FIG. 3, that are different from the width a 311 and the intensity c 313 of each of the channel A′ 211 and the channel B′ 221.

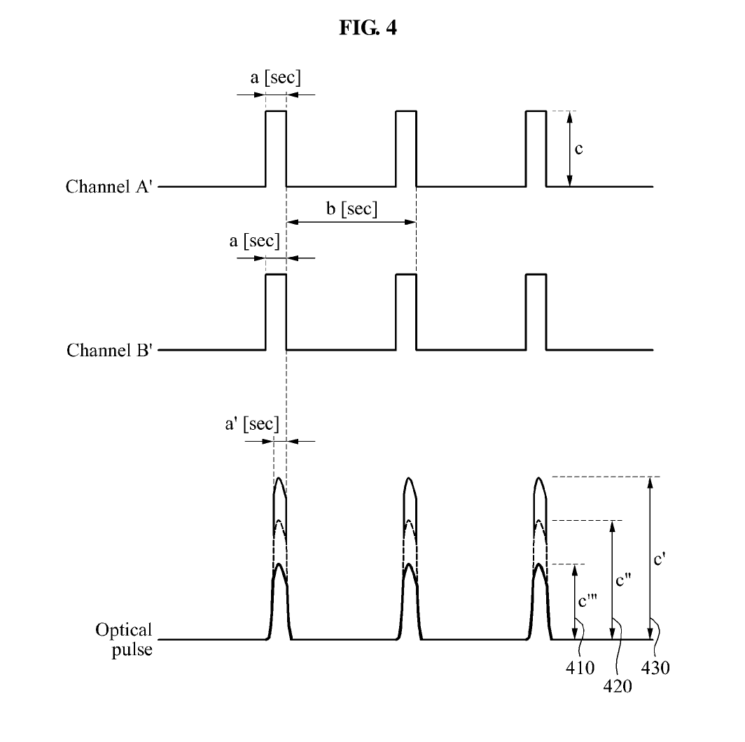

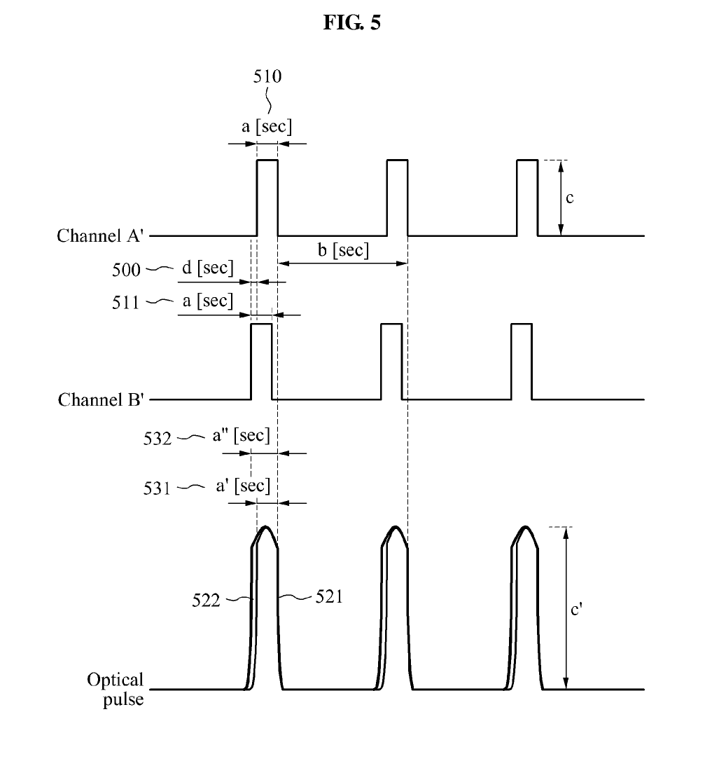

Hereinafter, a process by which the laser driver 120 changes the width a 311 and the intensity c 313 of the channel A′ 211 and the channel B′ 221 to the width a′ 321 and the intensity c′ 323 of the optical pulse 230 will be further described with reference to FIGS. 4 and 5.

FIG. 4 is a diagram illustrating an example of a change in an intensity of an optical pulse according to an embodiment of the present invention.

The maximum current controller 140 may control a maximum current, that is, a maximum value of a current transferred by the laser driver 120 to the laser 110.

In an example, the maximum current controller 140 may reduce the maximum current to a minimum value of the current transferred by the laser driver 120 to the laser 110. In this example, the intensity of the optical pulse 230 may be reduced to an intensity c″' 410, as shown in FIG. 4.

In another example, the maximum current controller 140 may control the maximum current to be an intermediate value of the current transferred by the laser driver 120 to the laser 110. In this example, the intensity of the optical pulse 230 may be determined to be an intensity c″ 420, as shown in FIG. 4.

In still another example, the maximum current controller 140 may increase the maximum current to a threshold of the current transferred by the laser driver 120 to the laser 110. In this example, the intensity of the optical pulse 230 may be increased to an intensity c′ 430, as shown in FIG. 4.

In other words, the intensity of the optical pulse 230 may be changed in proportion to the maximum current controlled by the maximum current controller 140.

FIG. 5 is a diagram illustrating an example of a change in a width of an optical pulse according to an embodiment of the present invention.

As shown in FIG. 5, the channel delay unit 130 may delay a channel B for a time d 500 in sec. Since the channel delay unit 130 does not change a width of each of a channel A and the channel B, a width a 510 of a channel A′ output by the channel delay unit 130 may be identical to a width a 511 of a channel B′.

However, since the laser driver 120 receives both the channel A′ and the channel B′, a width from a point in time 521, at which a change in the channel A′ begins, to a point in time 522, at which a change in the channel B′ ends, may be determined to be a width of an input channel.

For example, when a time difference between the channel A′ and the channel B′ does not exist, a point in time at which a change in channels received by the laser driver 120 begins, and a point in time at which the change in the channels ends may be identical to a point in time at which a change in the channel A and the channel B begins, and a point in time at which the change in the channel A and the channel B ends, respectively. Accordingly, a width a′ 531 of an optical pulse output by the laser 110 may be identical to the width a 510 of the channel A′, and the width a 511 of the channel B′.

Conversely, when the time difference between the channel A′ and the channel B′ corresponds to the time d 500, a point in time at which a change in channels received by the laser driver 120 begins may be different from a point in time at which a change in the channel B begins, and a point in time at which the change in the channels ends may be different from a point in time at which a change in the channel A ends. Additionally, the laser driver 120 may determine a width from the point in time 521 to the point in time 522 to be a width of an input channel.

Accordingly, a width a″ 532 of an optical pulse output by the laser 110 may be wider by the time d 500 than the width a 510 of the channel A′ and the width a 511 of the channel B′.

In other words, the channel delay unit 130 may delay a time of one of the channel A and the channel B by the time d 500, based on a width of an optical pulse that is to be increased, and may change the width of the optical pulse from the width a′ 531 to the width a″ 532.

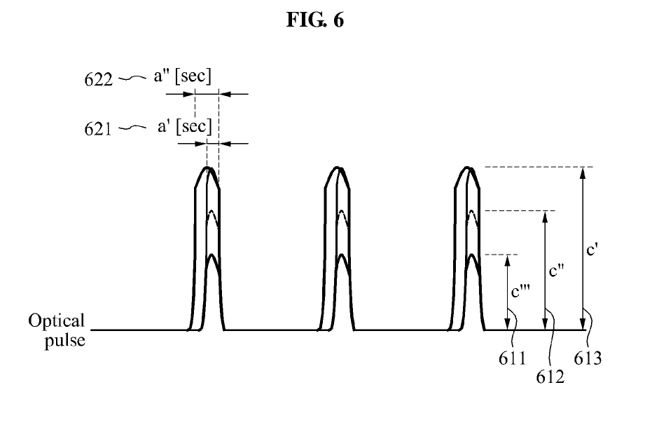

FIG. 6 is a diagram illustrating an example of a change in a width and an intensity of an optical pulse according to an embodiment of the present invention.

FIG. 6 illustrates a range in which a width and an intensity of an optical pulse are variable.

When the channel delay unit 130 may delay a time of one of two channels, the optical pulse output apparatus 100 may change the width of the optical pulse to a width between a width a′ 621 and a width a″ 622.

Additionally, when the maximum current controller 140 controls the maximum current, the optical pulse output apparatus 100 may change the intensity of the optical pulse to one of intensities c″' 611, c″ 612, and c′ 613. In FIG. 6, three maximum current values may be controlled by the optical pulse output apparatus 100. When a type of maximum current values controllable by the optical pulse output apparatus 100 is increased, the intensity of the optical pulse may be more diversely and closely changed.

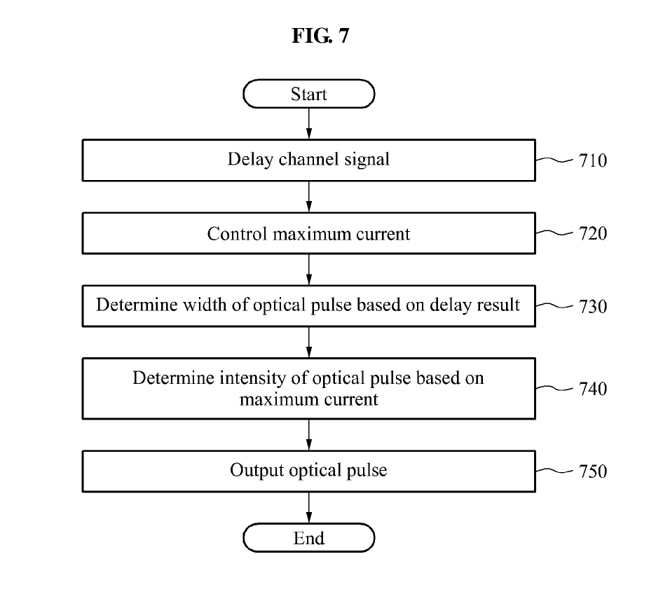

FIG. 7 is a flowchart of an optical pulse output method according to an embodiment of the present invention.

Referring to FIG. 7, in operation 710, the channel delay unit 130 may delay at least one of a plurality of channel signals input to the laser driver 120.

In operation 720, the maximum current controller 140 control a maximum current, that is, a maximum value of a current transferred by the laser driver 120 to the laser 110.

In operation 730, the laser driver 120 may determine a width of an optical pulse output by the laser 110, based on an amount of time by which the at least one channel signal is delayed, and whether the at least one channel signal is delayed.

For example, as an amount of time by which the channel delay unit 130 delays at least one channel signal increases, the laser driver 120 may increase a width of an optical pulse output by the laser 110. Additionally, when the channel delay unit 130 does not delay at least one of the plurality of channel signals, the laser driver 120 may determine the width of the optical pulse output by the laser 110, based on a width of each of the plurality of channel signals.

In operation 740, the laser driver 120 may determine an intensity of the optical pulse output by the laser 110, based on the maximum current controlled in operation 720.

For example, when the maximum current controller 140 increases the maximum current, the laser driver 120 may increase the intensity of the optical pulse output by the laser 110.

In operation 750, the laser 110 may output an optical pulse with the width determined in operation 730 and the intensity determined in operation 740.

As described above, according to embodiments of the present invention, it is possible to guarantee stability of a light source, and to freely change a width and an intensity of an optical pulse output by the light source, by delaying an external input channel, and by controlling a maximum current value.

Although a few exemplary embodiments of the present invention have been shown and described, the present invention is not limited to the described exemplary embodiments. Instead, it would be appreciated by those skilled in the art that changes may be made to these exemplary embodiments without departing from the principles and spirit of the invention, the scope of which is defined by the claims and their equivalents.

1. An optical pulse output apparatus, comprising:
a laser driver to drive a laser to output an optical pulse based on a plurality of channel signals, the optical pulse having a width;
a channel delay unit to change an amount of time by which at least one of the plurality of channel signals is delayed; and
the laser driver to further drive the laser to output an optical pulse having a changed width which is changed in accordance with the changed amount of time.

2-3. (canceled)

4. The optical pulse output apparatus of claim 1, wherein the channel delay unit changes the amount of time by increasing the amount of time, and wherein the laser driver further drives the laser to output an optical pulse having an increased width which is increased in accordance with the increased amount of time.

5. The optical pulse output apparatus of claim 1, wherein, when the channel delay unit does not delay the at least one channel signal, the laser driver determines the width of the optical pulse, based on a width of each of the plurality of channel signals.

6. The optical pulse output apparatus of claim 1, further comprising:
a maximum current controller to control a maximum current of the laser driver.

7. The optical pulse output apparatus of claim 6, wherein the laser driver determines an intensity of the optical pulse, based on the maximum current.

8. The optical pulse output apparatus of claim 6, wherein, when the maximum current increases, the laser driver increases the intensity of the optical pulse.

9-10. (canceled)

11. An optical pulse output method, comprising:
driving a laser to output an optical pulse based on a plurality of channel signals, the optical pulse having a width;
changing an amount of time by which at least one of the channel signals is delayed; and
driving the laser to output an optical pulse having a changed width which is changed in accordance with the changed amount of time.

12-13. (canceled)

14. The optical pulse output method of claim 11, wherein changing the amount of time comprises increasing the amount of time, and wherein driving the laser to output the optical pulse having the changed width comprises driving the laser to output an optical pulse having an increased width which is increased in accordance with the increased amount of time.

15. The optical pulse output method of claim 11, further comprising:
when the at least one channel signal is not delayed, determining the width of the optical pulse based on a width of each of the plurality of channel signals.

16. The optical pulse output method of claim 11, further comprising:
controlling a maximum current of a laser driver to drive the optical pulse.

17. The optical pulse output method of claim 16, wherein the controlling of the optical pulse comprises determining an intensity of the optical pulse, based on the maximum current.

18. The optical pulse output method of claim 16, wherein the controlling of the optical pulse comprises, when the maximum current increases, increasing the intensity of the optical pulse.

19-20. (canceled)
